(19) United States
(12) Patent Application Publication
(10) Pub. No.: US 2019/0334040 A1
(43) Pub. Date: Oct. 31, 2019

(54) SOLAR CELL SUBSTRATE AND SOLAR CELL COMPRISING SAME

(71) Applicant: LS-NIKKO COPPER INC., Ulsan (KR)

(72) Inventors: In Chul KIM, Yongin (KR); Min Soo KO, Seoul (KR); Chung Ho KIM, Namyangju (KR); Hwa Young NOH, Hwaseong (KR); Mun Seok JANG, Seoul (KR); Tae Hyun JUN, Seongnam (KR)

(73) Assignee: LS-Nikko Copper Inc., Ulsan (KR)

(21) Appl. No.: 16/346,068

(22) PCT Filed: Oct. 18, 2017
(86) PCT No.: PCT/KR2017/011509

§ 371 Date: Jun. 27, 2019

(30) Foreign Application Priority Data
Oct. 31, 2016 (KR) 10-2016-0143685

(51) Int. Cl. H01L 31/0224; H01L 31/04; H01L 31/0216

(52) U.S. Cl. CPC H01L 31/022441; H01L 31/02168; H01L 31/04

(57) ABSTRACT

The present invention provides a solar cell substrate on which an electrode is provided. The solar cell substrate includes the electrode having a lower printed layer formed by being printed with a conductive paste that contains a first metal powder and a first glass frit, and an upper printed layer formed by being printed on an upper surface of the lower printed layer with a conductive paste that contains a second metal powder and a second glass frit, and formed by sintering the lower and upper printed layers, wherein the second metal powder has an average particle diameter (D50) smaller than an average particle diameter (D50) of the first metal powder, and the second glass frit has a glass transition temperature higher than a glass transition temperature of the first glass frit.

### TECHNICAL FIELD

The present invention relates to a solar cell substrate and a solar cell having the same.

### BACKGROUND ART

As well known in the art, a solar cell, which is a semiconductor device that converts solar energy into electrical energy, is configured as a p-n junction and a basic structure thereof is the same as a diode. FIG. 1 shows a structure of a general solar cell device. The solar cell device is typically constituted by using a p-type silicon wafer 10 having a thickness of 180 to 250 μm. The p-type silicon wafer has an n-type impurity layer 20 having a thickness of 0.3 to 0.6 μm, an anti-reflective coating 30, and a front electrode 100 that are sequentially provided on a light receiving surface thereof. Furthermore, the p-type silicon wafer has a back electrode 50 provided on a back surface thereof. The front electrode 100 is made using a method in which a conductive paste, which contains silver powder, a glass frit, an organic vehicle, and additives, is applied on the anti-reflective coating 30 and then fired. The back electrode 50 is made using a method in which an aluminum paste, which contains aluminum powder, a glass frit, an organic vehicle, and additives, is applied on the back surface of the wafer through screen printing or the like and dried, and then fired at a temperature above 660° C. (melting point of aluminum). During aluminum paste firing, the aluminum is diffused into the p-type silicon wafer, whereby an Al—Si alloy layer is formed between the back electrode and the p-type silicon wafer. At the same time, a p+ layer 40 is formed as an impurity layer that results from diffusion of aluminum atoms. The existence of such a p+ layer makes it possible to obtain a back surface field (BSF) effect that prevents recombination of electrons and improves a collection efficiency of generated carriers. Furthermore, a silver back electrode 60 is provided on a lower surface of the back electrode 50.

The front electrode is typically comprised of a busbar electrode and a finger electrode. In order to achieve a high efficiency, a fine pattern is desired to be realized. However, there is a problem in that line breaks may occur and electrical characteristics may deteriorate during fine line-width printing and firing.

Documents of Related Art

(Patent Document 1) Korean Patent Application Publication No. 10-2013-0090276 (published on Aug. 13, 2013)

(Patent Document 2) Korean Patent Application Publication No. 10-2013-0104614 (published on Sep. 25, 2013)

### DISCLOSURE

### Technical Problem

Accordingly, the present invention has been made keeping in mind the above problem occurring in the related art, and an objective of the present invention is to provide a solar cell substrate and a solar cell having the same, in which a fine line width of an electrode is stably implemented, occurrence of line breaks is prevented, while providing an excellent aspect ratio and excellent adhesion with a substrate, thus improving solar cell efficiency.

However, the objectives of the present invention are not limited to the objective mentioned above, and other objectives not mentioned can be clearly understood by those skilled in the art from the following description.

### Technical Solution

In order to accomplish the above objective, according to an aspect of the present invention,

there is provided a solar cell substrate on which an electrode is provided and including: the electrode including a lower printed layer formed by being printed with a conductive paste that contains a first metal powder and a first glass frit, and an upper printed layer formed by being printed on an upper surface of the lower printed layer with a conductive paste that contains a second metal powder and a second glass frit, and formed by sintering the lower and upper printed layers, wherein the second metal powder has an average particle diameter (D50) smaller than an average particle diameter (D50) of the first metal powder, and the second glass frit has a glass transition temperature higher than a glass transition temperature of the first glass frit.

Furthermore, a difference between an average particle diameter of the first metal powder and an average particle diameter of the second metal powder may be within a range of greater than 0.1 μm to less than 0.4 μm.

Furthermore, a difference between a glass transition temperature of the first glass frit and a glass transition temperature of the second glass frit may be within a range of equal to or greater than 10° C. to equal to or less than 40° C.

Furthermore, an aspect ratio of the electrode may be within a range of greater than 0.42 to less than 0.50.

Furthermore, the second metal powder may be contained in an amount of equal to or greater than 89 wt % to equal to or less than 95 wt % with respect to a total weight of the conductive paste.

According to another aspect of the present invention, there is provided a solar cell having the solar cell substrate.

### Advantageous Effects

As described above, the present invention can solve the problem of line breaks which may occur in implementation of fine line width by implementing an electrode through at least two time printing processes and can improve the electrical characteristics by dramatically increasing the aspect ratio. Furthermore, when printing process is performed at least two times, a composition can be formulated such that the characteristics of silver powder and a glass frit are different from each other, thus making it possible to improve the printing characteristics and the adhesion characteristics and to prevent an increase in line width during firing.

### DESCRIPTION OF DRAWINGS

FIG. 1 is a schematic cross-sectional view showing a general solar cell device.

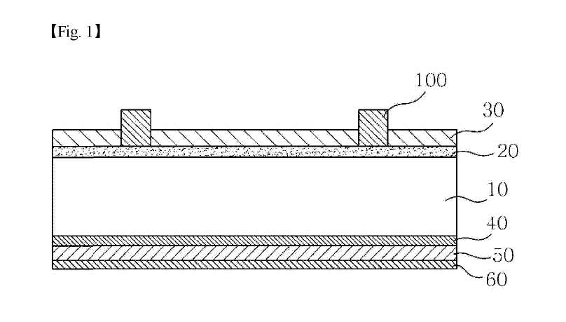

### MODE FOR INVENTION

Prior to describing the present invention in detail, it is to be understood that terms used in this specification are selected to describe embodiments and thus should not be construed as the limiting the spirit and scope of the present invention defined by the appended claims. Unless otherwise defined, all terms including technical and scientific terms used herein have the same meaning as commonly understood by one of ordinary skill in the art to which this invention belongs.

Unless otherwise defined, the terms “comprise”, “comprises”, and “comprising” when used in this specification and in the following claims are intended to specify the presence of stated features, elements, integers, components, or procedures, but they do not preclude the presence and/or addition of one or more other features, elements, integers, components, procedures, and/or combinations thereof.

Unless otherwise noted, various embodiments of the present invention may be combined with any other embodiments. In particular, any feature which is mentioned preferably or favorably may be combined with any other features which may be mentioned preferably or favorably. Hereinafter, a description will be given of exemplary embodiments of the present invention and effects thereof with reference to the accompanying drawings.

A solar cell substrate according to an embodiment of the present invention is a solar cell substrate on which an electrode is provided. The electrode includes: a lower printed layer formed by being printed with a conductive paste that contains a first metal powder and a first glass frit; and an upper printed layer formed by being printed on the upper surface of the lower printed layer with a conductive paste that contains a second metal powder and a second glass frit. The electrode is formed by sintering the lower and upper printed layers. The second metal powder has an average particle diameter (D50) smaller than an average particle diameter (D50) of the first metal powder. The second glass frit has a glass transition temperature higher than a glass transition temperature of the first glass frit.

The respective conductive pastes used for the lower printed layer and the upper printed layer may be the same except for differences described above and in detail below. Herein, the conductive paste for the lower printed layer is mainly described, and can be dedicated to a description of the conductive paste for the upper printed layer, except for specific differences.

The conductive paste for the lower and upper printed layers according to an embodiment of the present invention may contain metal powder, a glass frit, an organic vehicle, and the like. In addition, various additives may be contained.

The metal powder may be silver powder, copper powder, nickel powder, or aluminum powder. In the case of a front electrode, silver powder is mainly used, and in the case of a back electrode, aluminum powder is mainly used. Hereinbelow, the metal powder will be described by taking silver powder as an example for convenience. The following description may be equally applicable to other metal powders.

It is preferable that the metal powder is contained in an amount of 40 to 95 wt % with respect to a total weight of the conductive paste in consideration of the electrode thickness formed during printing and of the line resistance of the electrode.

It is preferable that the silver powder is a pure silver powder. Alternatively, a silver-coated composite powder at least having a silver layer on the surface thereof, or an alloy containing silver as a main component may be used. Furthermore, other metal powders may be mixed and used. For example, aluminum, gold, palladium, copper, and/or nickel powders may be used.

The silver powder may have an average particle diameter of 0.1 to 10 μm. It is preferable that the silver powder has an average particle diameter of 0.5 to 5 μm in consideration of ease of paste formation and of density during firing. The silver powder may have at least one of spherical, acicular, plate-like, and amorphous shapes. The silver powder may be a mixture of at least two powders that differ in average particle diameter, particle size distribution, and shape.

The composition, particle diameter, and shape of the glass frit are not particularly limited. The glass frit may be a leaded glass frit or a lead-free glass frit. It is preferable that the glass frit contains, in terms of oxides, PbO in an amount of 5 to 29 mol %, TeO₂ in an amount of 20 to 34 mol %, Bi₂O₃ in an amount of 3 to 20 mol %, SiO₂ in an amount of equal to or less than 20 mol %, B₂O₃ in an amount of equal to or less than 10 mol %, and an alkali metal (Li, Na, K, and the like) and an alkaline earth metal (Ca, Mg, and the like) in an amount of 10 to 20 mol %. Through organic combination of such components, it is possible to prevent an increase in line width of the electrode, to increase the contact resistance in high surface resistance, and to improve the short-circuit current characteristics.

The average particle diameter of the glass frit is not limited, but may be within a range of 0.5 to 10 μm. Furthermore, a mixture of various types of particles having different average particle diameters may be used. It is preferable that at least one type of glass frit has an average particle diameter (D50) of equal to or greater than 2 μm and equal to or less than 10 μm. As a result, it is possible to improve the reactivity during firing, to minimize damage to an n-layer at a high temperature, and to improve the adhesion, while improving the open-circuit voltage (VOC). Also, it is possible to prevent the electrode from being increased in line width during firing.

It is preferable that the glass frit is contained in an amount of 1 to 10 wt % with respect to a total weight of the conductive paste. When the amount of the glass frit is less than 1 wt %, incomplete firing may occur, leading to an increase in resistivity. When the amount of the glass frit is greater than 10 wt %, an excessive amount of glass component may be contained in a sintered body of the glass powder, leading to an increase in resistivity.

The organic vehicle may contain an organic binder, a solvent, and the like, but is not limited to. The use of the solvent may be omitted as the occasion demands. It is preferable that the organic vehicle is contained in an amount of 1 to 30 wt % with respect to a total weight of the conductive paste.

The organic vehicle is required to have ability of keeping a state in which the metal powder and the glass frit are uniformly mixed. For example, the organic vehicle is required to have ability of homogenizing the conductive paste when the conductive paste is applied to a wafer by screen printing so as to suppress blurring and collapse of a print pattern from occurring, and of improving the discharging performance and separability of the conductive paste from a screen plate.

Examples of the organic binder contained in the organic vehicle may include a cellulose ester compound such as cellulose acetate and cellulose acetate butyrate, a cellulose ether compound such as ethyl cellulose, methyl cellulose, hydroxypropyl cellulose, hydroxyethyl cellulose, hydroxypropyl methyl cellulose, and hydroxyethyl methyl cellulose, an acrylic compound such as polyacrylamide, polymethacrylate, polymethylmethacrylate, and polyethylmethacrylate, and a vinyl compound such as polyvinyl butyral, polyvinyl acetate, and polyvinyl alcohol, but are not limited thereto. At least one of the organic binders may be selected and used.

The solvent used for diluting the composition may be at least one selected from the group consisting of alpha-terpineol, texanol, dioctyl phthalate, dibutyl phthalate, cyclohexane, hexane, toluene, benzyl alcohol, dioxane, diethylene glycol, ethylene glycol monobutyl ether, ethylene glycol monobutyl ether acetate, diethylene glycol monobutyl ether, and diethylene glycol monobutyl ether acetate.

The additives may selectively use a dispersing agent, a thickening agent, a thixotropic agent, a leveling agent, and the like. Examples of the dispersing agent may include BYK-110, 111, 108, and 180. Examples of the thickening agent may include BYK-410, 411, and 420. Examples of the thixotropic agent may include BYK-203, 204, and 205. Examples of the leveling agent may include BYK-308, 378, and 3440. However, the present invention is not limited thereto.

In another embodiment of the present invention, the average particle diameter (D50) of the second metal powder is smaller than the average particle diameter (D50) of the first metal powder. It is preferable that the difference between the average particle diameter of the first metal powder and the average particle diameter of the second metal powder is within a range of greater than 0.1 μm to less than 0.4 μm, but the present invention is not limited thereto. Within the range, it is possible to achieve excellent electrical characteristics and adhesion characteristics and good printability, while preventing line breaks.

In still another embodiment of the present invention, the glass transition temperature of the second glass frit is higher than the glass transition temperature of the first glass frit. It is preferable that the difference between the glass transition temperature of the first glass frit and the glass transition temperature of the second glass frit is within a range of equal to or greater than 10° C. to equal to or less than 40° C., but the present invention is not limited thereto. Within the range, it is possible to prevent an increase in line width during firing, thus improving the aspect ratio.

In still another embodiment of the present invention, it is preferable that the second metal powder is contained in an amount of equal to or greater than 89 wt % to equal to or less than 95 wt % with respect to a total weight of the conductive paste for the upper printed layer. Below the range, there is problem in that the aspect ratio may significantly decrease, and the electrical characteristics may deteriorate. Above the range, there is problem in that the printability may deteriorate.

Hereinafter, the present invention will be described in more detail with reference to experimental examples.

### EXPERIMENTAL EXAMPLE 1

A paste composition for the lower printed layer of the electrode is as follows. For silver powder, 89.5 wt % of silver particles (produced by LS-Nikko Copper, and having an average particle diameter D50 of 2.2 μm and a tap density of 4.8 g/cm³) was added with respect to a total weight of the paste composition. For a glass frit, 2.5 wt % of a Pb—Te—Bi based material having a glass transition temperature (Tg) of 380° C. was added with respect to a total weight of the paste composition. For a resin, 1.5 wt % of STD-10 (produced by DOW) was added. For an additive, 0.5 wt % of Thixatrol Max (produced by Elementis) was added to impart thixotropic characteristics. For a dispersing agent, 1.5 wt % of ED-152 (produced by Kusumoto) was added. For a solvent, dibasic ester (DBE, containing dimethyl adipate, dimethyl glutrate, and dimethyl succinate and produced by TCI) and buthyl carbitol acetate (produced by Eastman) were added at a ratio of 1:1 to prepare a paste composition for the lower printed layer.

A paste composition for the upper printed layer of the electrode was prepared in the same manner as the paste composition for the lower printed layer except that silver powder having an average particle diameter (D50) of 2.0 μm was used.

In manufacturing a solar cell substrate, a 156 mm single-crystal silicon wafer was used. The wafer was doped with phosphorus (P) through a diffusion process using POCl₃ at 900° C. in a tube furnace to form a 100 to 500 nm-thick emitter layer having a sheet resistance of 90 Ω/sq. On the emitter layer, a silicon nitride coating was deposited by PECVD to form an 80 nm-thick anti-reflective coating. The front electrode was screen-printed on the upper surface of the anti-reflective coating. The lower printed layer of the front electrode was formed by screen-printing the prepared paste composition for the lower printed layer using a 28 μm mask with a printing machine by Baccini. In the same manner, the paste composition for the upper printed layer was screen-printed on the lower printed layer. The back electrode was screen-printed using a product of D company. Thereafter, the wafer was dried at 300° C. for 60 seconds in a BTU furnace, and then sintered in a firing furnace at 900° C. for 60 seconds to manufacture a solar cell substrate.

### EXPERIMENTAL EXAMPLE 2

The procedure was performed in the same manner as described in Experimental Example 1 except that the average particle diameter (D50) of the silver powder of the paste composition for the upper printed layer was 1.8 μm.

### EXPERIMENTAL EXAMPLE 3

The procedure was performed in the same manner as described in Experimental Example 1 except that the average particle diameter (D50) of the silver powder of the paste composition for the upper printed layer was 2.2 μm.

### EXPERIMENTAL EXAMPLE 4

The procedure was performed in the same manner as described in Experimental Example 1 except that the average particle diameter (D50) of the silver powder of the paste composition for the upper printed layer was 2.4 μm.

### EXPERIMENTAL EXAMPLE 5

The procedure was performed in the same manner as described in Experimental Example 1 except that the glass transition temperature (Tg) of the glass frit of the paste composition for the upper printed layer was 400° C.

### EXPERIMENTAL EXAMPLE 6

The procedure was performed in the same manner as described in Experimental Example 1 except that the glass transition temperature (Tg) of the glass frit of the paste composition for the upper printed layer was 360° C.

### EXPERIMENTAL EXAMPLE 7

The procedure was performed in the same manner as described in Experimental Example 1 except that the average particle diameter (D50) of the silver powder of the paste composition for the upper printed layer was 2.0 μm, and the glass transition temperature (Tg) of the glass frit was 400° C.

### EXPERIMENTAL EXAMPLE 8

The procedure was performed in the same manner as described in Experimental Example 1 except that the average particle diameter (D50) of the silver powder of the paste composition for the upper printed layer was 2.0 μm, and the glass transition temperature (Tg) of the glass frit was 360° C.

### EXPERIMENTAL EXAMPLE 9

The procedure was performed in the same manner as described in Experimental Example 1 except that the average particle diameter (D50) of the silver powder of the paste composition for the upper printed layer was 1.8 μm, the amount of the silver powder was 86 wt %, and the glass transition temperature (Tg) of the glass frit was 400° C.

### EXPERIMENTAL EXAMPLE 10

The procedure was performed in the same manner as described in Experimental Example 1 except that the average particle diameter (D50) of the silver powder of the paste composition for the upper printed layer was 1.8 μm, the amount of the silver powder was 83 wt %, and the glass transition temperature (Tg) of the glass frit was 400° C.

### EXPERIMENTAL EXAMPLE 11

The procedure was performed in the same manner as described in Experimental Example 1 except that the paste composition for the lower printed layer was screen-printed using a 35 μm mask, and a second printing process of the paste composition for the upper printed layer was omitted.

Test of Characteristics

The line width, height, aspect ratio, adhesion characteristics, and cell characteristics of Experimental Examples 1 to 10 were evaluated, and the results are shown in Table 1 below. IV characteristics/EL characteristics were measured using a tester by HALM Elektronik. The adhesion characteristics were measured using a tensile strength meter after bonding a SnPbAg-coated ribbon. The EL line breaks were visually observed.

TABLE 1

| | | Line | | | EL | | | | | | |
|---|---|---|---|---|---|---|---|---|---|---|---|
| | | Width | Height | Aspect | Line | Adhesion | | | | | |
| | Printability | (μm) | (μm) | Ratio | Breaks | (N/mm) | Isc (A) | Voc (V) | FF (%) | Rser (Ω) | Eff (%) |
| Experimental | OK | 38 | 16 | 0.42 | OK | 2.0 | 9.324 | 0.643 | 78.81 | 0.0019 | 19.55 |
| Example 1 | | | | | | | | | | | |
| Experimental | NG | 38 | 17 | 0.44 | NG | 2.2 | 9.324 | 0.642 | 78.41 | 0.0024 | 19.41 |
| Example 2 | | | | | | | | | | | |
| Experimental | OK | 38 | 16 | 0.42 | OK | 1.9 | 9.323 | 0.644 | 78.61 | 0.002 | 19.51 |
| Example 3 | | | | | | | | | | | |
| Experimental | OK | 38 | 15 | 0.39 | OK | 1.9 | 9.323 | 0.642 | 78.61 | 0.002 | 19.5 |
| Example 4 | | | | | | | | | | | |
| Experimental | OK | 37 | 17 | 0.46 | OK | 2.1 | 9.342 | 0.643 | 78.58 | 0.0021 | 19.61 |
| Example 5 | | | | | | | | | | | |
| Experimental | OK | 42 | 15 | 0.36 | OK | 2.0 | 9.32 | 0.64 | 78.51 | 0.002 | 19.46 |
| Example 6 | | | | | | | | | | | |
| Experimental | OK | 37 | 18 | 0.49 | OK | 2.2 | 9.354 | 0.643 | 78.81 | 0.0019 | 19.66 |
| Example 7 | | | | | | | | | | | |
| Experimental | OK | 40 | 16 | 0.4 | OK | 2.2 | 9.322 | 0.64 | 78.45 | 0.0021 | 19.43 |
| Example 8 | | | | | | | | | | | |
| Experimental | OK | 44 | 13 | 0.3 | OK | 1.7 | 9.27 | 0.641 | 78.11 | 0.0031 | 19.21 |
| Example 9 | | | | | | | | | | | |
| Experimental | OK | 47 | 11 | 0.23 | OK | 1.5 | 9.24 | 0.638 | 77.89 | 0.0035 | 19.05 |
| Example | | | | | | | | | | | |
| 10 | | | | | | | | | | | |
| Experimental | OK | 45 | 14 | 0.31 | NG | 1.9 | 9.32 | 0.643 | 78.41 | 0.0024 | 19.41 |
| Example | | | | | | | | | | | |
| 11 | | | | | | | | | | | |

As can be seen from the results, it was found that the production of the electrode by two time printing processes is excellent compared to the production of the electrode by a one time printing process in terms of prevention of line breaks, improvement of aspect ratio, and electrode efficiency. When printing process is performed two times, it was found that when the metal powder of the upper printed layer has a smaller particle diameter than that of the metal powder of the lower printed layer and when the glass transition temperature of glass frit of the upper printed layer is higher than that of the glass frit of the lower printed layer, the aspect ratio and the efficiency are excellent and which is also significantly affected by the amount of the silver powder. Meanwhile, it was found that when the difference in average particle diameter of the metal powders between the upper printed layer and the lower printed layer is equal to or greater than 0.4 μm, the printability deteriorates and line breaks occur. Therefore, it is preferable that the difference in average particle diameter of the metal powders is less than 0.4 μm. Meanwhile, it was found that when the amount of the metal powder of the upper printed layer is less than 89 wt %, the aspect ratio remarkably decreases and the adhesion deteriorates.

The features, structures, effects and so on illustrated in individual exemplary embodiments as above may be combined or modified with other exemplary embodiments by those skilled in the art. Therefore, content related to such combinations or modifications should be understood to fall within the scope of the present invention.

1. A solar cell substrate on which an electrode is provided and comprising:
the electrode including a lower printed layer formed by being printed with a conductive paste that contains a first metal powder and a first glass frit, and an upper printed layer formed by being printed on an upper surface of the lower printed layer with a conductive paste that contains a second metal powder and a second glass frit, and formed by sintering the lower and upper printed layers,
wherein the second metal powder has an average particle diameter (D50) smaller than an average particle diameter (D50) of the first metal powder, and
the second glass frit has a glass transition temperature higher than a glass transition temperature of the first glass frit.

2. The solar cell substrate of claim 1, wherein a difference between an average particle diameter of the first metal powder and an average particle diameter of the second metal powder is within a range of greater than 0.1 μm to less than 0.4 μm.

3. The solar cell substrate of claim 1, wherein a difference between a glass transition temperature of the first glass frit and a glass transition temperature of the second glass frit is within a range of equal to or greater than 10° C. to equal to or less than 40° C.

4. The solar cell substrate of claim 1, wherein an aspect ratio of the electrode is within a range of greater than 0.42 to less than 0.50.

5. The solar cell substrate of claim 1, wherein the second metal powder is contained in an amount of equal to or greater than 89 wt % to equal to or less than 95 wt % with respect to a total weight of the conductive paste.

6. A solar cell having the solar cell substrate of claim 1.
